(19) United States
(12) Patent Application Publication
(10) Pub. No.: US 2022/0199489 A1
(43) Pub. Date: Jun. 23, 2022

(54) GALLIUM ALLOYS AS FILLERS FOR POLYMER THERMAL INTERFACE MATERIALS

(71) Applicant: Intel Corporation, Santa Clara, CA (US)

(72) Inventors: Kyle ARRINGTON, Gilbert, AZ (US); Kosuke HIROTA, Portland, OR (US); Elah BOZORG-GRAYELI, Chandler, AZ (US)

(21) Appl. No.: 17/552,241

(22) Filed: Dec. 15, 2021

Related U.S. Application Data
(60) Provisional application No. 63/130,147, filed on Dec. 23, 2020.

(51) Int. Cl. H01L 23/373

(52) U.S. Cl. CPC H01L 23/3737

(57) ABSTRACT

Embodiments disclosed herein include polymer thermal interface materials. In an embodiment a thermal interface material (TIM) comprises a polymer matrix and a liquid metal filler in the polymer matrix. In an embodiment, the liquid metal filler comprises a liquid core and an oxide layer around the liquid core. In an embodiment, the liquid core comprises gallium or a gallium alloy, and the oxide layer comprises a metal oxide other than gallium oxide.

### CLAIM OF PRIORITY

This application claims priority to U.S. Provisional Application Ser. No. 63/130,147, filed on Dec. 23, 2020 and titled “GALLIUM ALLOYS AS FILLERS FOR POLYMER THERMAL INTERFACE MATERIALS,” which is incorporated by reference in its entirety.

### TECHNICAL FIELD

Embodiments of the disclosure are in the field of semiconductor structures and processing and, in particular, to liquid metal gallium alloys as fillers for polymer thermal interface materials (PTIMs).

### BACKGROUND

Liquid metal as a filler in polymeric resins is a material system of interest for use as a thermal interface material (TIM), among other possible applications. In one material system, gallium or a gallium alloy (e.g., gallium-indium, gallium-tin, or gallium-indium-tin) are mixed with a polymer resin to provide liquid metal domains in the polymer matrix. These unique systems can be highly loaded. Mixing and resin parameters control the particle size of the liquid metal domains from nanometers to hundreds of microns.

Currently, these systems suffer from potential reliability issues due to the liquid metal to polymer interface. With typical solid particle filled systems, ligands are used to bind to the oxide shell of the particle. For example, aluminum particles used in typical polymer based TIMs are decorated in silane coupling reagents that crosslink into the polymer matrix. These coupling reagents improve the reliability and time zero performance of the TIM. Gallium and traditional gallium alloys have a gallium oxide shell. This shell cannot be decorated with typical ligands used in the industry today, as they do not have the pendant hydroxyl groups that are utilized in coupling chemistries.

To overcome this challenge, water has been added to the liquid metal to generate a GaOOH shell which can readily react with polymer resins. However, adding water comes at a risk since the GaOOH shell is not self-passivating. This results in the water continuing to react with the gallium until the gallium is fully consumed, resulting in poor properties.

### BRIEF DESCRIPTION OF THE DRAWINGS

FIG. 1A is a SEM image of a polymer thermal interface material (PTIM) that comprises a liquid metal with a gallium liquid core and an oxide shell, in accordance with an embodiment.

FIG. 1B is an EDX analysis of the SEM image in FIG. 2A showing the gallium peaks, in accordance with an embodiment.

FIG. 1C is an EDX analysis of the SEM image in FIG. 2A showing the aluminum peaks, in accordance with an embodiment.

FIG. 2 is a dynamic scanning calorimetry (DSC) plot of a PTIM, in accordance with an embodiment.

FIG. 3 is a DSC plot showing the cooling and heating cycles, in accordance with an embodiment.

FIG. 4 is a cross-sectional illustration of an electronic system that includes a first PTIM and a second PTIM, in accordance with an embodiment.

FIG. 5 illustrates a computing device in accordance with one implementation of an embodiment of the disclosure.

### DESCRIPTION OF THE EMBODIMENTS

Embodiments described herein comprise liquid metal gallium alloys as fillers for polymer thermal interface materials (PTIMs). In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Liquid metal thermal interface materials (TIMs) allow for the material to readily fill in the micro-topology of the surface and provides a low interfacial resistance. This trait coupled with the material being a metal with a thermal conductivity in the 20 W/mK range allows the material to have low thermal impedance values. Providing a liquid metal in combination with a polymer resin allows for an even more robust material system. For example, the composite/emulsion of liquid metal and polymer resin is readily dispensable, does not corrode surfaces, and lowers the crystallization temperature of the liquid metal.

However, gallium forms an oxide shell or layer that does not meet reliability standards. As such, attempts to improve the particle shell by integration with the polymer have included adding water to the liquid metal to form OH bonds (particularly, a GaOOH layer) that can react with traditional coupling reagents. The disadvantage to using this method is that it requires an additional step to the manufacturing process (i.e., adding water and removing excess), and the potential for material excursions. If the water is not fully consumed or removed, there is a chance the water will outgas during the cure step of the material. This results in voids, which translates to a worse T₀ and reliability performance. A baking step can be introduced to remove the excess water, but this will add more manufacturing complexity. Finally, by introducing water, the potential to have differences between batches increases. Since the water will begin reacting right away with the GaO, mixing parameters and controlling the amount of water added is critical. Furthermore, since the GaOOH is not self-passivating to water, it will continue to grow in the presence of water unless the ligand can react with the surface. This potential for variability requires a more detailed specification for the certificate of conformance.

Accordingly, embodiments disclosed herein include a gallium alloy that will provide a novel oxide coating for improved surface stability and modification for an improved liquid to polymer coupling. PTIMs in accordance with embodiments described herein have been shown to be suitable for TIM 1 and TIM 2 applications. Particularly, in embodiments disclosed herein, the gallium is alloyed with a metal that will have an oxide with a lower Gibb's free energy than gallium oxide, which results in a different oxide shell. The new oxide shells provide improved ligand coupling to the gallium-based particle for improved reliability and performance.

In an embodiment, the liquid metal filler in polymeric resin comprises a liquid interior and an oxide shell or layer. It is to be appreciated that the filler maintains a liquid interior at temperatures typical of electronic devices, e.g., between approximately −50° C. and approximately 150° C. The liquid interior may comprise gallium, or other liquid metal alloys, such as gallium-indium, gallium-tin, gallium-indium-tin, or gallium-tin-zinc. The outer oxide shell may be a solid material at typical electronic device temperatures. In an embodiment, the outer oxide shell is formed by alloying the liquid metal filler with one or more metals that forms an oxide with a Gibb's free energy that is lower than that of gallium oxide. In a particular embodiment, the alloying element may comprise aluminum. However, it is to be appreciated that other elements may also be used. For example, Table 1 provides a list of elements and their corresponding oxides that may be used in some embodiments. It is to be appreciated that the listed “Formula of Oxide Shell” is only an example formula, and that the actual stoichiometry may be different in situ. For example, when the alloying element is aluminum, the stoichiometry of the oxide material in situ may be different than Al₂O₃. Therefore, such alloying may more broadly be characterized as including aluminum. For example, an outer oxide shell or layer in accordance with various embodiments includes alloying elements of Table 1 in combination with oxygen. For example, the outer oxide layer may include aluminum and oxygen in various stoichiometric proportions.

TABLE 1

| Alloying Element | Formula of Oxide Shell | Oxide Name |
|---|---|---|
| Europium | Eu₃O₄ | Europium(II-III) oxide |
| Tantalum | Ta₂O₅ | Tantalum(V) oxide |
| Scandium | Sc₂O₃ | Scandium oxide |
| Yttrium | Y₂O₃ | Yttrium oxide |
| Erbium | Er₂O₃ | Erbium oxide |
| Vanadium | V₃O₅ | Vanadium(III-IV) oxide |
| Thulium | Tm₂O₅ | Thulium oxide |
| Holmium | Ho₂O₃ | Holmium oxide |
| Lutetium | Lu₂O₃ | Lutetium oxide |
| Terbium | Tb₂O₃ | Terbium oxide |
| Dysprosium | Dy₂O₃ | Dysprosium(III) oxide |
| Niobium | Nb₂O₅ | Niobium(V) oxide |
| Samarium | Sm₂O₃ | Samarium(III) oxide |
| Gadolinium | Gd₂O₃ | Gadolinium(III) oxide |
| Ytterbium | Yb₂O₃ | Ytterbium(III) oxide |
| Praseodymium | Pr₂O₃ | Praseodymium oxide |
| Neodymium | Nd₂O₃ | Neodymium oxide |
| Cerium | Ce₃O₃ | Cerium(III) oxide |
| Lanthanum | La₂O₃ | Lanthanum oxide |
| Aluminum | Al₂O₃ | Aluminum oxide |
| Titanium | Ti₂O₃ | Titanium(III) oxide |
| Vanadium | V₂O₅ | Vanadium(V) oxide |
| Manganese | Mn₃O₄ | Manganese(II-III)oxide |
| Boron | B₂O₃ | Boron oxide |
| Thorium | ThO₂ | Thorium(IV) oxide |
| Uranium | UO₃ | Uranium(VI) oxide |
| Hafnium | HfO₂ | Hafnium oxide |
| Rhenium | Re₂O₇ | Rhenium(VII) oxide |
| Chromium | Cr₂O₃ | Chromium(III) oxide |
| Zirconium | ZrO₂ | Zirconium(IV) oxide |
| Iron | Fe₃O₄ | Iron(II-III)oxide |

In an embodiment, the alloying metal (e.g., from Table 1) may have a weight percent of the liquid metal of approximately 0.1%-10%. At these weight percentages, the outer shell will preferentially form as the oxide listed in Table 1 instead of forming the GaO shell. These oxide layers will have surface functionalities that can readily react with ligands to improve the reliability of the liquid metal PTIM. Furthermore, these oxide shells may allow for improved performance overall, compared to a GaO shell. For example, chromium oxide is known for its high stability, and zirconium oxide is electrically insulating. In addition to the metals included in Table 1, zinc may also be included as an additive to the liquid metal to provide further improvements for oxidation stability. For example, the zinc may have a weight percent of approximately 0.05% of the liquid metal PTIM.

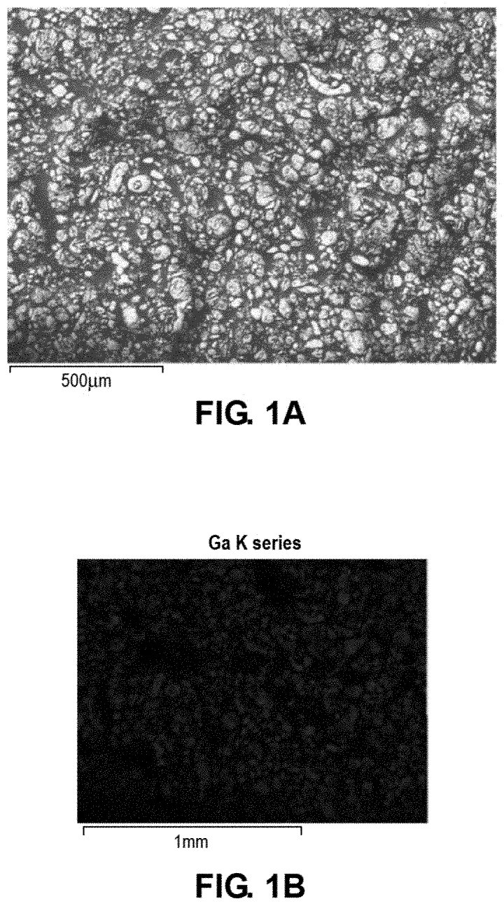

It is to be appreciated that various material analysis methods may be used in order to identify the presence of a liquid metal with an optimized oxide shell in a PTIM, such as the liquid metals described above. For example, a SEM/EDX analysis may be used. In an embodiment, the SEM image will show a highly loaded system of particles that do not look like traditional hard fillers, similar to the image shown in FIG. 1A. In FIG. 1A, the light regions are the liquid metal fillers. The specific alloy of FIG. 1A is a PTIM with a 60% (by volume) liquid metal that is a gallium-aluminum alloy, though similar images would be generated when other metal alloys from Table 1 are used.

Furthermore, an EDX analysis will show gallium and aluminum peaks that overlay on top of each other. For example, the gallium peaks are shown in FIG. 1B (the lighter regions) and the aluminum peaks are shown in FIG. 1C (the lighter regions). That is, if FIGS. 1B and 1C were overlaid over each other, the light regions in both figures would substantially overlap each other to indicate that the liquid metal comprises both gallium and aluminum. EDX may also be used to determine the ratio of the gallium to the aluminum. For example, in FIGS. 1B and 1C the gallium is 98% and the aluminum is 2%.

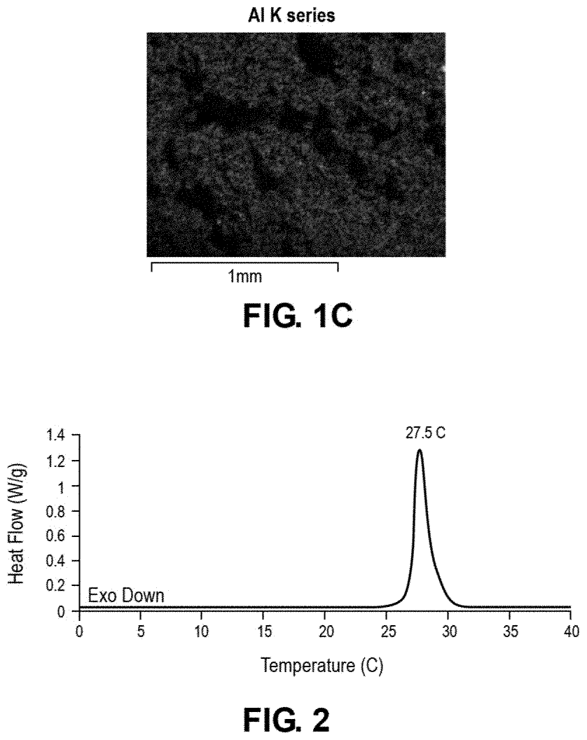

Another analytical method to determine the composition of the liquid metal is to use dynamic scanning calorimetry (DSC). A DSC plot of a gallium-aluminum sample is shown in FIG. 2. Particularly, the heating portion of the DSC plot is shown in FIG. 2. The peak of the DSC plot can be compared with a database of alloy melting temperatures. For example, the peak of 27.5° C. in FIG. 2 corresponds with the melting point for eutectic gallium-aluminum.

In an embodiment formation of the liquid metal alloy may comprise mixing gallium with high purity aluminum micro particles. The aluminum micro particles may be between approximately 0.1% by weight and approximately 10% by weight of the total alloy. After formation of the liquid metal alloy, the liquid metal may be mixed with a polymer resin, such as a silicone resin. The mixing may be implemented with a centrifugal mixer. In an embodiment, a volume percentage of the liquid metal alloy may be between approximately 30% and approximately 80%.

In a particular embodiment, the aluminum may comprise 2% by weight of the liquid metal alloy (with gallium at 98% by weight), and the liquid metal alloy may have a volume percentage of 60% (with a silicone resin having a volume percentage of 40%). Though it is to be appreciated that the liquid metal alloy may have a volume percentage between 20% and 90% in some embodiments. A PTIM with such a material composition may have particle sizes ranging from approximately 20 μm to approximately 200 μm. However, it is to be appreciated that the particle size and distribution can be readily tuned.

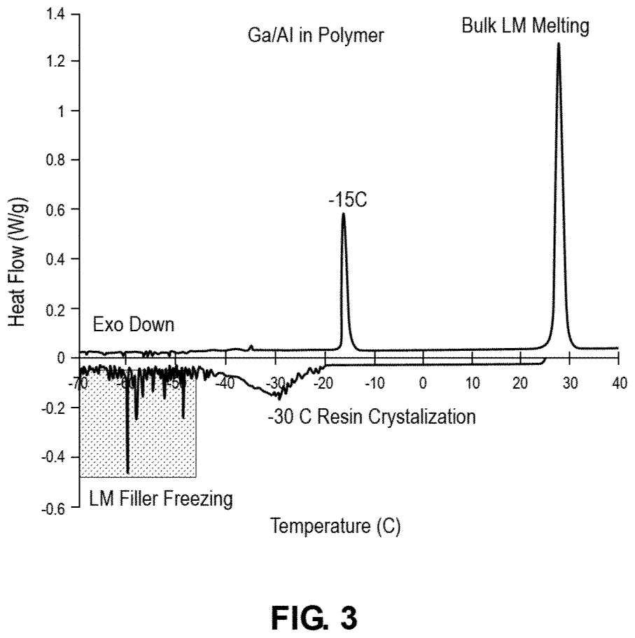

A PTIM with such a material composition was subjected to DSC analysis, which is shown in FIG. 3. During cooling, the characteristic shift for the liquid metal down to −50° C. and lower is shown. Here, particle size directly controls the crystallization temperature, where larger particles crystalize at higher temperatures and smaller particles crystalize at lower temperatures. This shift is due to the polymer resin preventing the liquid metal from being able to access the alpha crystalline phase for gallium. Particularly, the resin prevents the liquid metal from expanding in volume to arrange in the alpha crystalline phase. Larger particles are better at overcoming the polymer resin, resulting in a higher crystallization temperature. This makes the liquid metal stable at lower temperatures as long as the liquid metal is at the correct domain size. As shown in the heating portion of the DSC plot, the melting temperature is again shown at approximately 27.5° C. which is the melting temperature of eutectic gallium-aluminum.

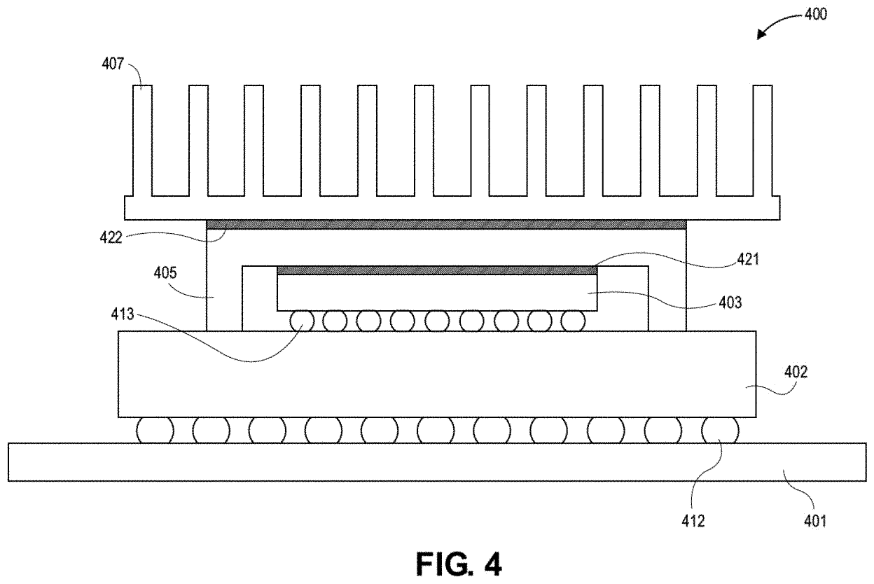

Referring now to FIG. 4, a cross-sectional illustration of an electronic system 400 is shown, in accordance with an embodiment. In an embodiment, the electronic system 400 comprises a board 401. The board 401 may be a printed circuit board (PCB) or the like. In an embodiment, a package substrate 402 is coupled to the board 401 by interconnects 412. The interconnects 412 are shown as solder balls, but it is to be appreciated that interconnects 412 may include any suitable architecture, such as sockets or the like.

In an embodiment, a die 403 may be coupled to the package substrate 402 by first level interconnects (FLIs) 413. The die 403 may be a computing die, a memory die, or any other active silicon (or other semiconductor) die. The FLIs 413 are shown as solder balls, but it is to be appreciated that FLIs 413 may comprise any interconnect architecture such as copper bumps or the like.

In an embodiment, an integrated heat spreader (IHS) 405 is thermally coupled to the die 403 by a first PTIM 421. The first PTIM 421 may be any PTIM such as those described in greater detail above. In a particular embodiment, the first PTIM 421 may comprise a liquid metal such as gallium, gallium-indium, gallium-tin, gallium-indium-tin, or gallium-tin-zinc. The liquid metal may further be alloyed with a metal from Table 1. The weight percent of the metal from Table 1 may be between approximately 0.1% and approximately 10%. The presence of the additional alloying metal may result in an oxide being formed around the liquid metal that comprises the metal from Table 1 instead of being a gallium oxide layer. The metal oxide shell provides improved coupling with the polymer matrix.

In an embodiment, the IHS 405 may be thermally coupled to a heatsink 407 or other thermal solution by a second PTIM 422. In the illustrated embodiment, the heatsink 407 comprises fins. However, the heatsink 407 may also comprise liquid cooling, heat pipes, or the like. In an embodiment, the second PTIM 422 may comprise a liquid metal such as gallium, gallium-indium, gallium-tin, gallium-indium-tin, or gallium-tin-zinc. The liquid metal may further be alloyed with a metal from Table 1. The weight percent of the metal from Table 1 may be between approximately 0.1% and approximately 10%. The presence of the additional alloying metal may result in an oxide being formed around the liquid metal that comprises the metal from Table 1 instead of being a gallium oxide layer. The metal oxide shell provides improved coupling with the polymer matrix.

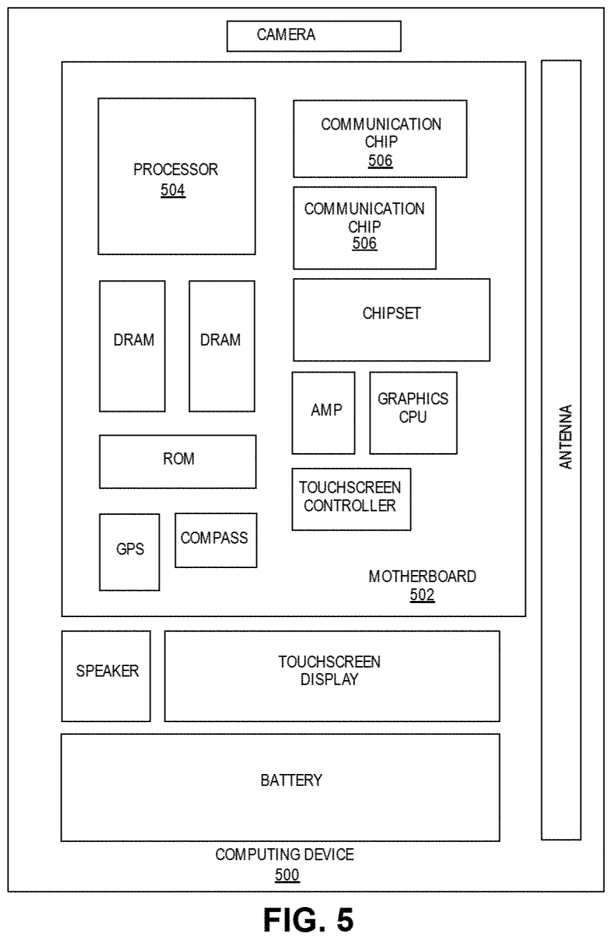

FIG. 5 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the invention, the integrated circuit die of the processor may be thermally coupled to an IHS by a PTIM that comprises a gallium based liquid metal with a metal oxide shell that comprises a metal other than gallium, in accordance with embodiments described herein. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the invention, the integrated circuit die of the communication chip may be thermally coupled to an IHS by a PTIM that comprises a gallium based liquid metal with a metal oxide shell that comprises a metal other than gallium, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a thermal interface material (TIM), comprising: a polymer matrix; and a liquid metal filler in the polymer matrix, wherein the liquid metal filler comprises a liquid core and an oxide layer around the liquid core, wherein the liquid core comprises gallium or a gallium alloy, and wherein the oxide layer comprises a metal oxide other than gallium oxide.

Example 2: the TIM of Example 1, wherein the gallium alloy comprises gallium-indium, gallium-tin, gallium-indium-tin, or gallium-tin-zinc.

Example 3: the TIM of Example 1 or Example 2, wherein the metal oxide comprises aluminum.

Example 4: the TIM of Example 3, wherein aluminum comprises between approximately 0.1% by weight and approximately 10% by weight of the liquid metal filler.

Example 5: the TIM of Example 4, wherein the aluminum comprises approximately 2% by weight of the liquid metal filler.

Example 6: the TIM of Examples 1-5, wherein the liquid metal filler has a volume percent of the TIM that is between approximately 20% and approximately 90%.

Example 7: the TIM of Examples 1-6, wherein the liquid metal filler comprises particle sizes between approximately 20 μm and approximately 200 μm.

Example 8: the TIM of Examples 1-7, wherein the polymer matrix comprises silicone resin.

Example 9: the TIM of Examples 1-8, wherein the polymer matrix comprises a volume percentage of the TIM that is between approximately 10% and approximately 80%.

Example 10; the TIM of Examples 1-9, wherein the TIM is between a die and an integrated heat spreader.

Example 11: the TIM of Example 10, wherein the TIM is further provided between the integrated heat spreader and a heatsink.

Example 12: an electronic package, comprising: a package substrate; a die coupled to the package substrate; an integrated heat spreader over the die; and a thermal interface material (TIM) between the die and the integrated heat spreader, wherein the TIM comprises: a polymer matrix; and a liquid metal filler in the polymer matrix, wherein the liquid metal filler comprises a liquid core and an oxide layer around the liquid core, wherein the liquid core comprises gallium or a gallium alloy, and wherein the oxide layer comprises a metal oxide other than gallium oxide.

Example 13: the electronic package of Example 12, wherein the gallium alloy comprises gallium-indium, gallium-tin, gallium-indium-tin, or gallium-tin-zinc.

Example 14: the electronic package of Example 12 or Example 13, wherein the metal oxide comprises aluminum.

Example 15: the electronic package of Example 14, wherein aluminum comprises between approximately 0.1% by weight and approximately 10% by weight of the liquid metal filler.

Example 16: the electronic package of Example 15, wherein the aluminum comprises approximately 2% by weight of the liquid metal filler.

Example 17: the electronic package of Examples 12-16, wherein the liquid metal filler has a volume percent of the TIM that is between approximately 20% and approximately 90%.

Example 18: the electronic package of Examples 12-17, wherein the liquid metal filler comprises particle sizes between approximately 20 μm and approximately 200 μm.

Example 19: the electronic package of Examples 12-18, wherein the polymer matrix comprises silicone resin.

Example 20: the electronic package of Examples 12-19, wherein the polymer matrix comprises a volume percentage of the TIM that is between approximately 10% and approximately 80%.

Example 21: the electronic package of Examples 12-20, further comprising: a heatsink over the integrated heat spreader, wherein the heatsink is coupled to the integrated heat spreader by a second TIM.

Example 22: the electronic package of Example 21, wherein the second TIM comprises the polymer matrix and the liquid metal filler.

Example 23: an electronic system, comprising: a board; a package substrate coupled to the board; a die coupled to the package substrate; an integrated heat spreader over the die; and a thermal interface material (TIM) between the die and the integrated heat spreader, wherein the TIM comprises: a polymer matrix; and a liquid metal filler in the polymer matrix, wherein the liquid metal filler comprises a liquid core and an oxide layer around the liquid core, wherein the liquid core comprises gallium or a gallium alloy, and wherein the oxide layer comprises a metal oxide other than gallium oxide.

Example 24: the electronic system of Example 23, wherein the gallium alloy comprises gallium-indium, gallium-tin, gallium-indium-tin, or gallium-tin-zinc.

Example 25: the electronic system of Example 23 or Example 24, wherein the metal oxide comprises aluminum.

What is claimed is:

1. A thermal interface material (TIM), comprising:
a polymer matrix; and
a liquid metal filler in the polymer matrix, wherein the liquid metal filler comprises a liquid core and an oxide layer around the liquid core, wherein the liquid core comprises gallium or a gallium alloy, and wherein the oxide layer comprises a metal oxide other than gallium oxide.

2. The TIM of claim 1, wherein the gallium alloy comprises gallium-indium, gallium-tin, gallium-indium-tin, or gallium-tin-zinc.

3. The TIM of claim 1, wherein the metal oxide comprises aluminum.

4. The TIM of claim 3, wherein aluminum comprises between approximately 0.1% by weight and approximately 10% by weight of the liquid metal filler.

5. The TIM of claim 4, wherein the aluminum comprises approximately 2% by weight of the liquid metal filler.

6. The TIM of claim 1, wherein the liquid metal filler has a volume percent of the TIM that is between approximately 20% and approximately 90%.

7. The TIM of claim 1, wherein the liquid metal filler comprises particle sizes between approximately 20 μm and approximately 200 μm.

8. The TIM of claim 1, wherein the polymer matrix comprises silicone resin.

9. The TIM of claim 1, wherein the polymer matrix comprises a volume percentage of the TIM that is between approximately 10% and approximately 80%.

10. The TIM of claim 1, wherein the TIM is between a die and an integrated heat spreader.

11. The TIM of claim 10, wherein the TIM is further provided between the integrated heat spreader and a heatsink.

12. An electronic package, comprising:
a package substrate;
a die coupled to the package substrate;
an integrated heat spreader over the die; and
a thermal interface material (TIM) between the die and the integrated heat spreader, wherein the TIM comprises:
a polymer matrix; and
a liquid metal filler in the polymer matrix, wherein the liquid metal filler comprises a liquid core and an oxide layer around the liquid core, wherein the liquid core comprises gallium or a gallium alloy, and wherein the oxide layer comprises a metal oxide other than gallium oxide.

13. The electronic package of claim 12, wherein the gallium alloy comprises gallium-indium, gallium-tin, gallium-indium-tin, or gallium-tin-zinc.

14. The electronic package of claim 12, wherein the metal oxide comprises aluminum.

15. The electronic package of claim 14, wherein aluminum comprises between approximately 0.1% by weight and approximately 10% by weight of the liquid metal filler.

16. The electronic package of claim 15, wherein the aluminum comprises approximately 2% by weight of the liquid metal filler.

17. The electronic package of claim 12, wherein the liquid metal filler has a volume percent of the TIM that is between approximately 20% and approximately 90%.

18. The electronic package of claim 12, wherein the liquid metal filler comprises particle sizes between approximately 20 μm and approximately 200 μm.

19. The electronic package of claim 12, wherein the polymer matrix comprises silicone resin.

20. The electronic package of claim 12, wherein the polymer matrix comprises a volume percentage of the TIM that is between approximately 10% and approximately 80%.

21. The electronic package of claim 12, further comprising:
a heatsink over the integrated heat spreader, wherein the heatsink is coupled to the integrated heat spreader by a second TIM.

22. The electronic package of claim 21, wherein the second TIM comprises the polymer matrix and the liquid metal filler.

23. An electronic system, comprising:
a board;
a package substrate coupled to the board;
a die coupled to the package substrate;
an integrated heat spreader over the die; and
a thermal interface material (TIM) between the die and the integrated heat spreader, wherein the TIM comprises:
a polymer matrix; and
a liquid metal filler in the polymer matrix, wherein the liquid metal filler comprises a liquid core and an oxide layer around the liquid core, wherein the liquid core comprises gallium or a gallium alloy, and wherein the oxide layer comprises a metal oxide other than gallium oxide.

24. The electronic system of claim 23, wherein the gallium alloy comprises gallium-indium, gallium-tin, gallium-indium-tin, or gallium-tin-zinc.

25. The electronic system of claim 23, wherein the metal oxide comprises aluminum.
